(19) United States
(12) Patent Application Publication
(10) Pub. No.: US 2004/0067424 A1
(43) Pub. Date: Apr. 8, 2004

(54) Protective device for lithographic masks and method of using lithographic masks

(76) Inventors: Christof Matthias Schilz, Munchen (DE); Frank-Michael Kamm, Unterhaching (DE)

Correspondence Address: LERNER AND GREENBERG, P.A., POST OFFICE BOX 2480, HOLLYWOOD, FL, 33022-2480, US

(21) Appl. No.: 10/681,488

(22) Filed: Oct. 8, 2003

(30) Foreign Application Priority Data
Oct. 8, 2002 (DE) 102 46 788.9

(51) Int. Cl. G03F 9/00

(52) U.S. Cl. 430/5

(57) ABSTRACT

A protective device for plate-shaped objects, such as lithographic masks, includes at least one holding element with a planar edge and a protective element for protecting at least one surface of a plate-shaped object. A polymer cushion, which is disposed on the planar edge, can be brought into contact with a peripheral region of the surface of the plate-shaped object. The polymer cushion is formed of a polymer whose viscosity and/or adhesiveness is greater when tensile forces are exerted on the protective device orthogonally in relation to the peripheral region of the plate-shaped object than when shearing forces are exerted on the protective device parallel to the peripheral region. A method of using such a protected plate-shaped object is also provided.

### BACKGROUND OF THE INVENTION

### FIELD OF THE INVENTION

The invention relates to a protective device for plate-shaped objects such as lithographic masks, in particular reflection masks, and to a method of using a protected plate-shaped object such as a photolithographic mask.

For EUV (extreme ultraviolet) lithography or X-ray lithography of integrated circuits, so-called reflection masks are used. In this method of wafer exposure, the exposure source in the wafer exposure device radiates onto the reflection mask at a fixed angle. On the surface of the mask there are milled-in or etched-in structures, which have been calculated through the use of mathematical methods and at which the light is reflected and diverted onto the wafer through the use of reflection mirror optics. The reflection patterns created in this way contain the structure information of the mask and in this way expose the wafer. An especially critical aspect of the use of this mask technique is the requirement for absolute freedom from defects with respect to the mask structures, in order to obtain wafer structures that are exposed without any defects. Any particle located on the reflection mask disturbs the reflection at this point and leads to imaging errors on the wafer, which can lead to the failure of such defectively exposed integrated circuits.

In conventional transmission-optical lithographies, masks are protected from subsequent particle contamination by a polymer membrane, a so-called pellicle. The pellicle is a thin, usually polymeric membrane, which is stretched over a frame to form a protective skin at a distance of several millimeters (for example 5 to 10 mm) from the surface of the mask. Particles falling on it up to a size of about 200 μm are outside the focal plane, i.e. the mask surface, in optical imaging and are therefore not projected onto the wafer. The pellicle is usually mounted in the final step of production of a mask and is intended to remain permanently on it, serving both as protection during transport and also protection during use in the exposure device.

However, on account of the special conditions in EUV lithography, in particular the high energy of the radiation sources used, the use of these protective membranes is not possible during the exposure of the wafer. Even the use of pellicles as a temporary protection during transport and storage has so far been ruled out, since the removal of the pellicle frame adhesively bonded securely to the reflection mask is laborious and leads to massive particle contamination. Other mechanical solutions known in the prior art for the protection of the reflection mask lead to unacceptable states of stress in the mask and consequently to distortion of the mask structures, which is reflected in inaccurate imaging on the wafer surface and accompanying defects of the integrated circuits. Consequently, the use of reflection masks has until now been extremely laborious, since they were used and stored without protection, which entailed continual cleaning steps.

### SUMMARY OF THE INVENTION

It is accordingly an object of the invention to provide a protection device for plate-shaped objects which overcomes the above-mentioned disadvantages of the heretofore-known protection devices of this general type and which provides protection for reflection masks that can be restored without any problems or any stress. It is a further object of the invention to provide a method of using a protected plate-shaped object.

With the foregoing and other objects in view there is provided, in accordance with the invention, a protection configuration for a plate-shaped object, including:

a protective device including at least one holding element and a polymer cushion;

the at least one holding element having a planar edge;

the at least one holding element having a protective element configured to protect a surface of the plate-shaped object;

the polymer cushion being disposed on the planar edge and configured to contact a peripheral region of the surface of the plate-shaped object; and

the polymer cushion being formed of a polymer having at least one property selected from the group consisting of a viscosity and an adhesiveness, at least one of the viscosity and the adhesiveness being greater when tensile forces are exerted on the protective device orthogonally in relation to the peripheral region of the plate-shaped object than when shearing forces are exerted on the protective device parallel to the peripheral region of the plate-shaped object.

In other words, according to the invention, there is provided a protective device for plate-shaped objects, including:

at least one holding element with a planar first edge and a protective element for protecting at least one surface of a plate-shaped object;

a polymer cushion which is disposed on the first edge and can be brought into contact with a peripheral region of the surface;

the polymer cushion being formed of a polymer of which the viscosity and/or adhesiveness is greater when tensile forces are exerted on the protective device orthogonally in relation to the peripheral region of the object than when shearing forces are exerted on the protective device parallel to the peripheral region.

The invention is based on the idea of connecting a reflection mask and a protective device with an adhesive or viscous polymer which can produce different forces of resistance in different directions. Even if use is mainly directed at the protection of photolithographic masks, it goes without saying that other objects can also be protected.

The polymers involved in this case have properties of non-Newtonian fluids, which are pressure-sensitive and gel-like.

Consequently provided is a protective element of which the planar edge, i.e. an edge located on one plane, could be placed onto the generally likewise planar object surface of the object, etc. In order to establish a connection between the two elements, however, a polymer cushion is then applied to the edge and establishes an adhesive connection between the edge and consequently the protective element and the surface of the object. It goes without saying that this connection is to take place in a peripheral region or a number of peripheral regions of the object, peripheral regions being intended here to be understood as those regions which preferably lie outside a region to be protected of the object, for example the reflection structures on a lithographic mask, and consequently do not have to be protected or on which residues of the polymer cushion are acceptable. Alternatively, the peripheral region may also be chosen such that, for example in the case of structures reaching up to the edge, it still lies within the structure pattern of the mask, the mask then being cleaned before operation. The essence of the invention lies in the selection of a polymer satisfying the requirement defined in the claims. This polymer has two preferential directions with respect to its adhesive or viscous behavior, preferably orthogonal to each other. It is oriented in the polymer cushion in such a way that it has a relatively greater adhesive effect in the case of tensile forces which act orthogonally in relation to the surface of the object or the peripheral regions, and consequently can be regarded as separating forces, as occur for example when the plate-shaped object or the like on the protective device is raised, than in the case of forces which act parallel to the peripheral regions of the surface, and consequently would bring about sliding of the protective device on the object. It can be achieved in this way that, on the one hand, the object can be transported on the protective device and the protective device is not thereby simply lifted off from the object, but that, on the other hand, before the object is used, the protective device can be separated from the object in a simple manner by moving it laterally and then be removed. Stresses are dissipated and an improvement in the positioning accuracy of the structures created with the mask takes place.

As already stated and illustrated by way of example, the plate-shaped object is preferably a lithographic mask, in particular a reflection mask for use in EUV lithography.

Polymers or polymer blends that are suitable in practice for the invention are those which have the properties of typical PSA (pressure sensitive adhesive) materials or “release coatings”. For this class of materials, the Theological Dahlquist criterion of creep behavior (J) of a minimally required 10⁶ cm²/dyn at service temperature applies. PSA materials have at a glass transition value Tg of −25° C. typical G′ moduli of greater than 10⁶ dyn/cm². Their peeling behavior (G′) increases greatly with the peel rate. Typical representatives are, for instance, TESA 7475™, polydimethoxysilane or polydimethyl siloxane or EASTOTAC™ PSAs based on low molecular weight aliphatic hydrocarbon resins.

The protective device according to the invention is preferably a protective shroud which has: as the holding element, a frame with a wall running laterally around it and with the planar first edge on the wall, and, as the protective element, a membrane stretched over the frame, covering the entire frame, such that it is possible for the frame to be placed with its polymer cushion onto the peripheral region of the plate-shaped object. This embodiment of the present invention corresponds substantially to the construction of previous pellicle-frame/mask configurations, in which the frames also remain on the masks during exposure. The decisive difference is, however, that the object or mask and the frame are connected to each other through the use of the special polymer cushion and can consequently be separated in a simple way before the mask is used.

The frame may have a second edge, substantially parallel to the first edge, the membrane being fastened to the second edge. In this way, a distance is achieved between the membrane and the surface of the object/mask.

The wall of the frame may have a height of 5 to 10 mm, measured from the surface of the object to the membrane, which in the field of lithographic masks corresponds substantially to the situation in the case of conventional pellicle frames.

A conventional pellicle, such as are sold for instance by Microlithography Inc., may serve as the protective device. The polymer cushion is in this case provided on the frame edge that is facing away from the membrane. The optical properties of the polymer film are insignificant in this instance.

In an alternative embodiment, the invention may be embodied as a closable box for receiving a plate-shaped object, such as a mask, and has a cover and a base, projections which respectively have a planar edge with polymer cushions disposed on them being provided as holding elements on the cover and on the base, and it being possible for the plate-shaped object to be secured between the polymer cushions of the projections. In this way, the plate-shaped object is secured both on its upper side and on its underside, which permits particularly secure transport and good protection against environmental influences. In the case of this embodiment of the present invention, a departure is made from the concept of the classical pellicle frame by providing an optimized storing device for a photolithographic mask.

The projections may be configured in a way similar to the edges of the pellicle frame, but it is also possible to provide projections optimized for the respective intended use and optimized to the weight or centrifugal masses of the plate-shaped object to be protected, such as photolithographic masks.

The box according to the invention may additionally have a viewing/inspection window, in order to permit, for example, an inspection of masks. This viewing window preferably has the property of a DUV (deep ultraviolet) transmission or transparency in the wavelength range of 157-365 nm, with the consequence that an inspection carried out under corresponding light is possible without removing the mask from the box.

The cover of the box is preferably configured in such a way that it can be removed by a pushing movement or a turning movement. In this way, the shearing forces necessary for separating the object and projections, which serve for overcoming the viscosity of the polymer cushions, can be exerted in a simple manner. Hinged covers, on the other hand, are less advantageous, since they would cause an orthogonal movement of the polymer cushions, which would bring about higher holding forces of reaction of the cushions and possibly tearing of them, with the consequent formation of residues on the object.

The limit value of the exertable orthogonal tensile forces (that is to say forces directed away from the object surface) under which the adhesion of the polymer cushion is not overcome should be great enough that, during usual handling, the protective device remains fixed to the surface and the limit value of the exertable parallel shearing forces (that is to say forces which are exerted substantially parallel to the object surface) under which the adhesion of the polymer cushion is not overcome should be small enough that it is possible for it to be overcome by manual or mechanical lateral displacement of the components in relation to each other.

According to another feature of the invention, the plate-shaped object is a lithographic mask.

According to yet another feature of the invention, the polymer of the polymer cushion is TESA 7475, polydimethoxysilane or EASTOTAC PSAs based on low-molecular-weight aliphatic hydrocarbon resins.

According to another feature of the invention, the at least one holding element is a frame with a wall extending laterally all around, the planar edge is provided on the wall such that the frame can be placed with the polymer cushion onto the peripheral region of the plate-shaped object; and the protective element is a membrane stretched over the frame and covering the frame entirely such that the protective device forms a protective shroud.

According to a further feature of the invention, the planar edge of the wall is a first edge; the frame has a second edge provided substantially parallel to the first edge; and the membrane is fastened to the second edge.

According to another feature of the invention, the membrane is formed of a polymer or a crystalline material.

According to another feature of the invention, the protective device is a pellicle frame; and the polymer cushion is provided on the planar edge facing away from the membrane.

According to yet another feature of the invention, the protective device is a closable box for receiving the plate-shaped object; the closable box has a cover and a base; and projections are provided as holding elements at the cover and the base, the projections have respective planar edges with polymer cushions disposed on the planar edges such that the plate-shaped object can be secured between the polymer cushions of the projections.

According to another feature of the invention, the closable box has a viewing/inspection window.

According to another feature of the invention, the cover of the closable box is removable by a pushing movement or a turning movement.

According to another feature of the invention, the protective device has a first limit value for exertable orthogonal tensile forces that are too small to overcome an adhesion of the polymer cushion, wherein the first limit value is selected large enough such that the adhesion of the polymer cushion is not overcome during usual handling and such that the protective device remains fixed to the surface of the plate-shaped object; and the protective device has a second limit value for exertable parallel shearing forces that are too small to overcome an adhesion of the polymer cushion, wherein the second limit value is selected small enough such that the adhesion of the polymer cushion can be overcome by manual or mechanical lateral displacement.

The invention is further directed at a method of using a plate-shaped object. All that has been described with respect to the device also applies to the method presented below, and vice versa, so that reference is made reciprocally between them.

With the objects of the invention in view there is also provided, a method of using a protected plate-shaped object, the method includes the steps of:

providing a configuration with a plate-shaped object and a protective device having at least one holding element with a planar edge, a protective element for protecting at least one surface of the plate-shaped object, a polymer cushion disposed on the planar edge and in contact with a peripheral region of the surface of the plate-shaped object, the polymer cushion being formed of a polymer having a viscosity and/or an adhesiveness that is greater when tensile forces are exerted on the protective device orthogonally in relation to the peripheral region of the plate-shaped object than when shearing forces are exerted on the protective device parallel to the peripheral region;

separating the plate-shaped object and the protective device by exerting an adequate shearing force resulting in a lateral relative movement of the plate-shaped object and the protective device for overcoming the adhesion;

using the plate-shaped object for an intended purpose; and

connecting the plate-shaped object and the protective device to one another by bringing the plate-shaped object and the protective device orthogonally together with respect to the surface and the edge.

In other words, according to the invention, the method of using a protected photolithographic mask according to the invention has the following steps:

providing a configuration with a plate-shaped object and a protective device with at least one holding element with a planar first edge, a protective element for protecting at least one surface of the plate-shaped object, a polymer cushion which is arranged on the first edge and is in contact with a peripheral region of the surface of the object, the polymer cushion formed of a polymer of which the viscosity and/or adhesiveness is greater when tensile forces are exerted on the protective device orthogonally in relation to the peripheral region of the object than when shearing forces are exerted on the protective device parallel to the peripheral region;

separating the object and the protective device by exerting an adequate shearing force, which leads to a lateral relative movement of the object and the protective device for overcoming the adhesion;

using the object for an intended purpose; and

after the completion of use, connecting the object and the protective device by bringing the object and the protective device orthogonally together with respect to the surface and the edge.

The method is consequently aimed at exerting a movement or application of force parallel to the surface of the object when separating the protective element and the plate-shaped object, in order to allow the two elements to be separated from each other, and placing the two elements orthogonally one on the other when joining them together, in order to re-establish the forces of adhesion.

The plate-shaped object is preferably a lithographic mask, for example a reflection mask, and is used for the exposure of a wafer.

In particular, it is preferred that the protective device used for the method according to the invention is a protective device according to the invention as disclosed above.

After the separating of the protective device and the plate-shaped object, the method according to the invention may have the further step of cleaning the object of residues of the polymer cushion.

In this way, residues of the polymer cushion possibly remaining behind on the plate-shaped object can be removed and in this way the occurrence of defects during the exposure of wafers can be avoided, in particular in the region of mask structures in the case of masks.

The cleaning is preferably carried out by irradiation with a xenon UV excimer lamp under an O₂/N₂ gas mixture, which has been found to be effective for the removal of residues of the polymer cushion.

According to another mode of the invention, the closable box is provided with a viewing/inspection window; and the viewing/inspection window is used for an inspection with DUV light.

According to another mode of the invention, a wavelength range of 157 nm to 365 nm is used for the inspection.

Other features which are considered as characteristic for the invention are set forth in the appended claims.

Although the invention is illustrated and described herein as embodied in a protective device for lithographic masks and a method of using them, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic sectional view of a first embodiment according to the invention with a construction similar to a conventional pellicle frame; and

FIG. 2 is a diagrammatic sectional view of a further embodiment according to the invention wherein the photolithographic mask is protected by a box.

### DESCRIPTION OF THE PREFERRED EMBODIMENTS

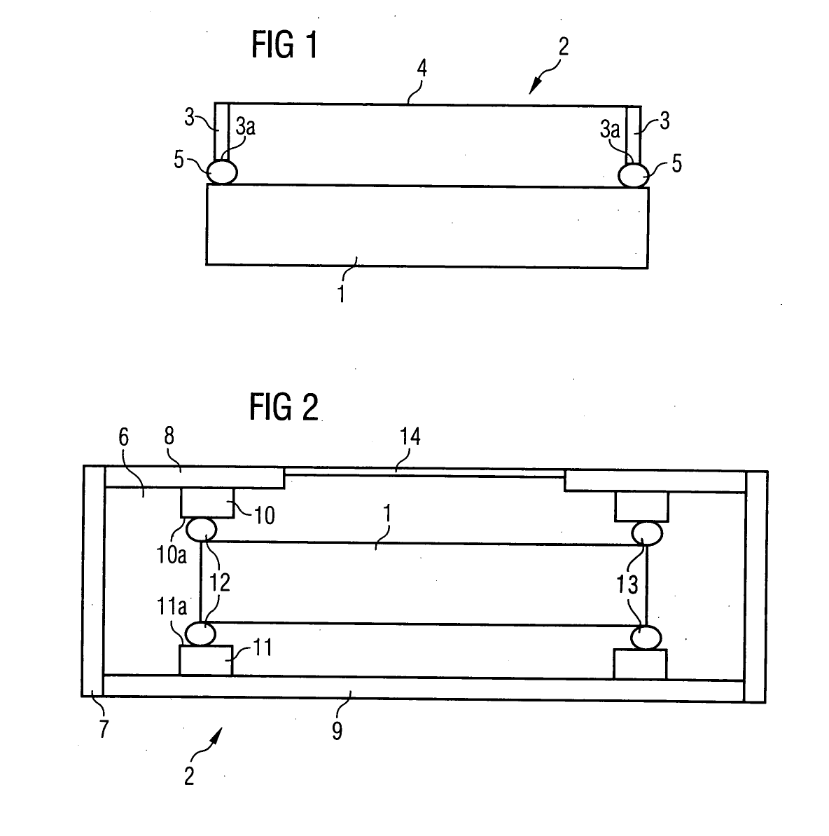

Referring now to the figures of the drawings in detail and first, particularly, to FIG. 1 thereof, there is shown a protective device according to the present invention. The protective device uses polymer cushions, including polymers specifically suited for this purpose, for the connection of the protective device to the photolithographic mask to be protected. They may be applied for example to conventional pellicle frames, and these frames can be used as temporary particle protection. The adhesive forces can be overcome, and the pellicle detached from the mask without particles being additionally created, by slight mechanical shearing forces. Slight organic residues possibly occurring thereby in the case of a rupture in the adhesive-cohesive bond in the polymer close to the surface of the mask lie in monolayer regions and can therefore be removed within minutes by brief irradiation of the mask with an Xe UV excimer lamp in an O₂/N₂ gas mixture.

FIG. 1 shows a first embodiment of the present invention, in which a photolithographic mask 1 is to be protected by a protective device 2 on its upper side. The protective device 2 has a frame 3, which may correspond for example to a customary pellicle frame, and also a membrane 4 including a polymer or a metal foil or the like. An advantage in the case of the present invention is the great extensibility of the material used for the membrane, since no regard has to be paid to the transparency, since the membrane merely serves for protection from particles during storage and transport but does not remain on the mask during the actual exposure process. Metal foils are therefore also suited here for use as the membrane. If desired, the membrane may also be thicker, in order in this way to ensure better mechanical protection. According to the invention, between an edge 3a of the frame 3 and the mask 1 there is a polymer cushion 5 including the specific polymers described above with preferential directional properties. The polymer cushion brings about an adherence of the protective device 2 to the mask 1 and thereby ensures its protection against particle deposition.

In FIG. 2, the concept of the protective device is further developed into a protective box completely surrounding the mask. The mask 1 is inside the protective device 2, which is a box 6. The box 6 has side walls 7, a cover 8 and a base 9. Arranged on the cover 8 are projections 10 and arranged on the base 9 are projections 11. Respectively arranged on the edges 10a, 11a of the projections are polymer cushions 12 and 13. The projections 10 and 11 are dimensioned in such a way that, together with the polymer cushion, they protrude so far into the box that they can secure between the polymer cushions the mask 1 that is to be received. In this way, protection can be achieved against influences both on the structure side of the mask 1 and on the other surface of the mask 1. If appropriate, the cover 8 of the box 6 may contain an inspection window 14 of a transparent material, for example made of glass or of a polymer, in order to permit an inspection of the mask located under it, or establishment of the presence of the mask.

The particular advantage of the present invention lies in the introduction of a novel inexpensive adhering technique for frames on lithographic masks or other plate-shaped objects with sensitive surfaces that are to be protected. The invention is not restricted in its intended use to reflection masks, although it has been developed with regard to these, but can also be used for example for translucent masks. Other objects that can be referred to as masks and the surface of which is to remain free of particles during storage can also be protected with it. Fields of use are, for example, in the optical industry, where it is desirable for highly clean surfaces to be maintained during intermediate stages of product manufacture, in order to prevent the ingress of dust particles or the like in photographic lenses or telescopes for example. Further fields of use lie within the range of knowledge of a person skilled in the art in the field of particle protection technology. Use of the polymers referred to also allows conventional inexpensive standard pellicles to be used for the protection of photolithographic masks. This saves costs and development time. Furthermore, the problem of contact-induced particle creation is obviated by the use of highly viscous soft polymers. Instances of outgassing of the materials used are clearly identified and their elimination through the use of Xe lamps causes no problems.

We claim

1. In combination with a plate-shaped object having a surface with a peripheral region, a protection configuration for the plate-shaped object, comprising:
a protective device including at least one holding element and a polymer cushion;
said at least one holding element having a planar edge;
said at least one holding element having a protective element configured to protect the surface of the plate-shaped object;
said polymer cushion being disposed on said planar edge and configured to contact the peripheral region of the surface of the plate-shaped object; and
said polymer cushion being formed of a polymer having at least one property selected from the group consisting of a viscosity and an adhesiveness, at least one of the viscosity and the adhesiveness being greater when tensile forces are exerted on the protective device orthogonally in relation to the peripheral region of the plate-shaped object than when shearing forces are exerted on the protective device parallel to the peripheral region of the plate-shaped object.

2. The protection configuration according to claim 1, wherein the plate-shaped object is a lithographic mask.

3. The protection configuration according to claim 1, wherein said polymer of said polymer cushion is a material selected from the group consisting of TESA 7475, polydimethoxysilane and EASTOTAC PSAs based on low-molecular-weight aliphatic hydrocarbon resins.

4. The protection configuration according to claim 1, wherein:
said at least one holding element is a frame with a wall extending laterally all around, said planar edge is provided on said wall such that said frame can be placed with said polymer cushion onto the peripheral region of the plate-shaped object; and
said protective element is a membrane stretched over said frame and covering said frame entirely such that said protective device forms a protective shroud.

5. The protection configuration according to claim 4, wherein:
said planar edge of said wall is a first edge;
said frame has a second edge provided substantially parallel to said first edge; and
said membrane is fastened to said second edge.

6. The protection configuration according to claim 4, wherein said membrane is formed of a material selected from the group consisting of a polymer and a crystalline material.

7. The protection configuration according to claim 4, wherein said wall of said frame has a height of 5 mm to 10 mm, measured from the surface of the plate-shaped object to the membrane.

8. The protection configuration according to claim 4, wherein:
said protective device is a pellicle frame; and
said polymer cushion is provided on said planar edge facing away from said membrane.

9. The protection configuration according to claim 1, wherein:
said protective device is a closable box for receiving the plate-shaped object;
said closable box has a cover and a base; and
projections are provided as holding elements at said cover and said base, said projections have respective planar edges with polymer cushions disposed on said planar edges such that the plate-shaped object can be secured between said polymer cushions of said projections.

10. The protection configuration according to claim 9, wherein said closable box has a viewing/inspection window.

11. The protection configuration according to claim 9, wherein said cover of said closable box is removable by one of a pushing movement and a turning movement.

12. The protection configuration according to claim 1, wherein:
said protective device has a first limit value for exertable orthogonal tensile forces that are too small to overcome an adhesion of said polymer cushion, wherein the first limit value is selected large enough such that the adhesion of said polymer cushion is not overcome during usual handling and such that said protective device remains fixed to the surface of the plate-shaped object; and
said protective device has a second limit value for exertable parallel shearing forces that are too small to overcome an adhesion of said polymer cushion, wherein the second limit value is selected small enough such that the adhesion of said polymer cushion can be overcome by manual or mechanical lateral displacement.

13. A method of using a protected plate-shaped object, the method which comprises:
providing a configuration with a plate-shaped object and a protective device having at least one holding element with a planar edge, a protective element for protecting at least one surface of the plate-shaped object, a polymer cushion disposed on the planar edge and in contact with a peripheral region of the surface of the plate-shaped object, the polymer cushion being formed of a polymer having at least one of a viscosity and an adhesiveness that is greater when tensile forces are exerted on the protective device orthogonally in relation to the peripheral region of the plate-shaped object than when shearing forces are exerted on the protective device parallel to the peripheral region;
separating the plate-shaped object and the protective device by exerting an adequate shearing force resulting in a lateral relative movement of the plate-shaped object and the protective device for overcoming the adhesion;
using the plate-shaped object for an intended purpose; and
connecting the plate-shaped object and the protective device to one another by bringing the plate-shaped object and the protective device orthogonally together with respect to the surface and the edge.

14. The method according to claim 13, which comprises using a lithographic mask as the plate-shaped object.

15. The method according to claim 13, which comprises cleaning the plate-shaped object of residues of the polymer cushion subsequent to the separating step.

16. The method according to claim 15, which comprises carrying out an irradiation step with a xenon UV excimer lamp under an O₂/N₂ gas mixture for cleaning the plate-shaped object.

17. The method according to claim 13, which comprises using, as the polymer of the polymer cushion, a material selected from the group consisting of TESA 7475, polydimethoxysilane and EASTOTAC PSAs based on low-molecular-weight aliphatic hydrocarbon resins.

18. The method according to claim 13, which comprises:
providing the at least one holding element as a frame with a wall extending laterally all around, and providing the planar edge on the wall such that the frame can be placed with the polymer cushion onto the peripheral region of the plate-shaped object; and
using, as the protective element, a membrane stretched over the frame and covering the frame entirely such that the frame and the membrane form a protective shroud.

19. The method according to claim 18, which comprises:
providing a further edge of the frame substantially parallel to the edge; and
fastening the membrane to the further edge.

20. The method according to claim 18, which comprises forming the membrane of a material selected from the group consisting of a polymer and a crystalline material.

21. The method according to claim 18, which comprises providing the wall of the frame with a height of 5 mm to 10 mm, measured from the surface of the plate-shaped object to the membrane.

22. The method according to claim 18, which comprises:
using a pellicle frame as the protective device; and
providing the polymer cushion on the planar edge facing away from the membrane.

23. The method according to claim 13, which comprises:
using, as the protective device, a closable box for receiving the plate-shaped object;
providing the closable box with a cover and a base; and
providing projections as holding elements at the cover and the base and providing the projections with respective planar edges with polymer cushions disposed on the planar edges such that the plate-shaped object can be secured between the polymer cushions of the projections.

24. The method according to claim 23, which comprises providing a viewing/inspection window for the closable box.

25. The method according to claim 23, which comprises providing the cover of the closable box such that the cover can be removed by one of pushing and turning the cover.

26. The method according to claim 13, which comprises:
selecting a first limit value for exertable orthogonal tensile forces that are too small to overcome an adhesion of the polymer cushion by selecting the first limit value large enough such that the adhesion of the polymer cushion is not overcome during usual handling and such that the protective device remains fixed to the surface of the plate-shaped object; and
selecting a second limit value for exertable parallel shearing forces that are too small to overcome an adhesion of the polymer cushion by selecting the second limit value small enough such that the adhesion of the polymer cushion can be overcome by manual or mechanical lateral displacement.

27. The method according to claim 23, which comprises:
providing the closable box with a viewing/inspection window; and
using the viewing/inspection window for an inspection with DUV light.

28. The method according to claim 27, which comprises using a wavelength range of 157 nm to 365 nm for the inspection.
